(19) United States
(12) Patent Application Publication
(10) Pub. No.: US 2020/0287017 A1
(43) Pub. Date: Sep. 10, 2020

(54) SINGLE TRANSISTOR WITH STRAINED AND DE-POLARIZING ANTI-FERROELECTRIC AND FERROELECTRIC OXIDE

(71) Applicant: Intel Corporation, Santa Clara, CA (US)

(72) Inventors: Sou-Chi CHANG, Portland, OR (US); Chia-Chang LIN, Portland, OR (US); Seung Hoon SUNG, Portland, OR (US); Ashish Verma PENUMATCHA, Hillsboro, OR (US); Nazila HARATIPOURA, Hillsboro, OR (US); Owen LOH, Portland, OR (US); Jack KAVALIEROS, Portland, OR (US); Uygar AVCI, Portland, OR (US); Ian YOUNG, Portland, OR (US)

(73) Assignee: Intel Corporation, Santa Clara, CA (US)

(21) Appl. No.: 16/294,821

(22) Filed: Mar. 6, 2019

(51) Int. Cl. H01L 29/51; H01L 29/78; H01L 29/66

(52) U.S. Cl. CPC H01L 29/516; H01L 29/6684; H01L 29/78391; H01L 29/517

(57) ABSTRACT

A gate stack is described that uses anti-ferroelectric material (e.g., Si, La, N, Al, Zr, Ge, Y doped HfO2) or ferroelectric material (e.g., Si, La, N, Al, Zr, Ge, Y doped HfO2, perovskite ferroelectric such as NH4H2PO4, KH2PO4, LiNb03, LiTaO3, BaTiO3, PbTiO3, Pb (Zr,Ti) O3, (Pb,La)TiO3, and (Pb,La)(Zr,Ti)O3) which reduces write voltage, improves endurance, and increases retention. The gate stack of comprises strained anti-FE or FE material and depolarized anti-FE or FE. The endurance of the FE transistor is further improved by using a higher K (constant) dielectric (e.g., SiO2, Al2O3, HfO2, Ta2O3, La2O3) in the gate stack. High K effects may also be achieved by depolarizing the FE or FE oxide in the transistor gate stack.

### BACKGROUND

In a typical ferroelectric transistor based memory, high write voltage is required to achieve reasonable memory window. Memory window is a performance parameter, which is inversely proportional to endurance cycle. To have large memory window, high polarization is desired for the ferroelectric material of the ferroelectric transistor. High polarization can be achieved by increasing the electric field across the gate of the ferroelectric transistor, where the ferroelectric material is part of the gate. The gate also includes low K dielectric for high mobility under the gate in the transistor channel region. Typical ferroelectric transistor uses about 3 volt (V) potential difference across its gate to switch the ferroelectric material of the gate. However, a high electric field (e.g., 3V) across the gate, and hence across the low-K dielectric, breaks the transistor at an early endurance cycle. Further, memory retention is limited by large depolarization field induced by the inter-layer, which includes the low K dielectric.

The background description provided here is for the purpose of generally presenting the context of the disclosure. Unless otherwise indicated here, the material described in this section is not prior art to the claims in this application and are not admitted to be prior art by inclusion in this section.

### BRIEF DESCRIPTION OF THE DRAWINGS

The embodiments of the disclosure will be understood more fully from the detailed description given below and from the accompanying drawings of various embodiments of the disclosure, which, however, should not be taken to limit the disclosure to the specific embodiments, but are for explanation and understanding only.

FIG. 1 illustrates a cross-section of a ferroelectric (FE) transistor that suffers from high write energy and low endurance cycle.

FIG. 2 illustrates a plot showing epitaxial strain for a FE material (e.g., ZrO2).

FIGS. 3A-B illustrate a three-dimensional (3D) view and corresponding cross-sectional view, respectively, of a planar FE transistor with strained and depolarizing FE and/or anti-FE gate stack, where the depolarizing FE and/or anti-FE is adjacent to a channel region, in accordance with some embodiments.

FIGS. 4A-B illustrate a 3D view and corresponding cross-sectional view, respectively, of a planar FE transistor with strained and depolarizing FE and/or anti-FE gate stack, where the strained FE and/or anti-FE is adjacent to a channel region, in accordance with some embodiments.

FIGS. 5A-B illustrate a 3D view and corresponding cross-sectional view, respectively, of a planar FE transistor with strained FE and/or anti-FE and high-K dielectric gate stack, where the high-K dielectric is adjacent to a channel region, in accordance with some embodiments.

FIGS. 6A-B illustrate a 3D view and corresponding cross-sectional view, respectively, of a planar FE transistor with strained FE and/or anti-FE and high-K dielectric gate stack, where the strained FE and/or anti-FE is adjacent to a channel region, in accordance with some embodiments.

FIGS. 7A-B illustrate a 3D view and corresponding cross-sectional view, respectively, of a finFET FE transistor with strained and depolarizing FE and/or anti-FE gate stack, where the depolarizing FE and/or anti-FE is adjacent to a channel region, in accordance with some embodiments.

FIGS. 8A-B illustrate a 3D view and corresponding cross-sectional view, respectively, of a finFET FE transistor with strained and depolarizing FE and/or anti-FE gate stack, where the strained FE and/or anti-FE is adjacent to a channel region, in accordance with some embodiments.

FIGS. 9A-B illustrate a 3D view and corresponding cross-sectional view, respectively, of a finFET FE transistor with strained FE and/or anti-FE and high-K dielectric gate stack, where the high-K dielectric is adjacent to a channel region, in accordance with some embodiments.

FIGS. 10A-B illustrate a 3D view and corresponding cross-sectional view, respectively, of a finFET FE transistor with strained FE and/or anti-FE and high-K dielectric gate stack, where the strained FE and/or anti-FE is adjacent to a channel region, in accordance with some embodiments.

FIG. 11 illustrates a flowchart of a method for forming an FE transistor with strained and depolarizing FE or anti-FE gate stack, in accordance with some embodiments.

FIG. 12 illustrates a smart device, a computer system, or a SoC (System-on-Chip) with strained and depolarizing FE or anti-FE gate stack, according to some embodiments of the disclosure.

### DETAILED DESCRIPTION

One way to reduce high write voltage and improve retention of ferroelectric (FE) transistors is to engineer super-lattice type deposition of doped Hafnium (Hf). This engineered super-lattice type deposition of doped Hf improves the FE response so that the corresponding write voltage can be reduced. However, tuning the FE properties by engineering the super-lattice-type deposition is not enough to reduce the write voltage small enough for memory options.

Some embodiments use an anti-ferroelectric or ferroelectric (FE) gate stack in a transistor structure that reduces write voltage, improves endurance, and increases retention. The gate stack of some embodiments comprises strained anti-FE or FE material and depolarized anti-FE or FE. In some embodiments, endurance of the FE transistor is improved by using a higher K (constant) dielectric in the gate stack. Examples of high K dielectric include: SiO2, Al2O3, HfO2, Ta2O3, and/or La2O3. In some embodiments, when atomic layer deposition (ALD) is used to grow the oxide, doped HfO2 can be realized in the form of super-lattice. In some embodiments, high K effects or high dielectric responses are also achieved by depolarizing the FE or FE oxide in the transistor gate stack.

The gate stack of some embodiments can be used for fabricating a planar Field Effect Transistor (FET) or a non-planar transistor or a combination of both. Nonplanar transistors include FinFET transistors such as double-gate transistors and tri-gate transistors, and wrap-around or all-around gate transistors such as nanoribbon and nanowire transistors. Other transistors within the scope of various embodiments include Tunneling FET (TFET), Square Wire, or Rectangular Ribbon Transistors, or other devices implementing transistor functionality like carbon nanotubes or spintronic devices. Metal Oxide Semiconductor (MOSFET) have symmetrical source and drain terminals i.e., are identical terminals and are interchangeably used here. A TFET device, on the other hand, has asymmetric Source and Drain terminals. Those skilled in the art will appreciate that other transistors, for example, Bi-polar junction transistors (BJT PNP/NPN), BiCMOS, CMOS, etc., may be used with the gate stack of various embodiments without departing from the scope of the disclosure.

There are many technical effects of the various embodiments. For example, by making the effective dielectric constant for the gate stack higher (compared to traditional FE gate stacks), the electric field across the dielectric of the gate stack is reduced which allows for more voltage across the FE material of the gate stack for a give gate voltage. As such, the write voltage is reduced compared to the write voltage of traditional FE transistors. Other technical effects will be evident from the various embodiments and figures.

In the following description, numerous details are discussed to provide a more thorough explanation of embodiments of the present disclosure. It will be apparent, however, to one skilled in the art, that embodiments of the present disclosure may be practiced without these specific details. In other instances, well-known structures and devices are shown in block diagram form, rather than in detail, in order to avoid obscuring embodiments of the present disclosure.

Note that in the corresponding drawings of the embodiments, signals are represented with lines. Some lines may be thicker, to indicate more constituent signal paths, and/or have arrows at one or more ends, to indicate primary information flow direction. Such indications are not intended to be limiting. Rather, the lines are used in connection with one or more exemplary embodiments to facilitate easier understanding of a circuit or a logical unit. Any represented signal, as dictated by design needs or preferences, may actually comprise one or more signals that may travel in either direction and may be implemented with any suitable type of signal scheme.

The term “device” may generally refer to an apparatus according to the context of the usage of that term. For example, a device may refer to a stack of layers or structures, a single structure or layer, a connection of various structures having active and/or passive elements, etc. Generally, a device is a three-dimensional structure with a plane along the x-y direction and a height along the z direction of an x-y-z Cartesian coordinate system. The plane of the device may also be the plane of an apparatus which comprises the device.

Throughout the specification, and in the claims, the term “connected” means a direct connection, such as electrical, mechanical, or magnetic connection between the things that are connected, without any intermediary devices.

The term “coupled” means a direct or indirect connection, such as a direct electrical, mechanical, or magnetic connection between the things that are connected or an indirect connection, through one or more passive or active intermediary devices.

The term “adjacent” here generally refers to a position of a thing being next to (e g , immediately next to or close to with one or more things between them) or adjoining another thing (e.g., abutting it).

The term “circuit” or “module” may refer to one or more passive and/or active components that are arranged to cooperate with one another to provide a desired function.

The term “signal” may refer to at least one current signal, voltage signal, magnetic signal, or data/clock signal. The meaning of “a,” “an,” and “the” include plural references. The meaning of “in” includes “in” and “on.”

The term “scaling” generally refers to converting a design (schematic and layout) from one process technology to another process technology and subsequently being reduced in layout area. The term “scaling” generally also refers to downsizing layout and devices within the same technology node. The term “scaling” may also refer to adjusting (e.g., slowing down or speeding up—i.e. scaling down, or scaling up respectively) of a signal frequency relative to another parameter, for example, power supply level.

The terms “substantially,” “close,” “approximately,” “near,” and “about,” generally refer to being within +/−10% of a target value. For example, unless otherwise specified in the explicit context of their use, the terms “substantially equal,” “about equal” and “approximately equal” mean that there is no more than incidental variation between among things so described. In the art, such variation is typically no more than +/−10% of a predetermined target value.

Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

The terms “left,” “right,” “front.” “back,” “top,” “bottom,” “over,” “under,” and the like in the description and in the claims, if any, are used for descriptive purposes and not necessarily for describing permanent relative positions. For example, the terms “over,” “under,” “front side,” “back side,” “top,” “bottom,” “over,” “under,” and “on” as used herein refer to a relative position of one component, structure, or material with respect to other referenced components, structures or materials within a device, where such physical relationships are noteworthy. These terms are employed herein for descriptive purposes only and predominantly within the context of a device z-axis and therefore may be relative to an orientation of a device. Hence, a first material “over” a second material in the context of a figure provided herein may also be “under” the second material if the device is oriented upside-down relative to the context of the figure provided. In the context of materials, one material disposed over or under another may be directly in contact or may have one or more intervening materials. Moreover, one material disposed between two materials may be directly in contact with the two layers or may have one or more intervening layers. In contrast, a first material “on” a second material is in direct contact with that second material. Similar distinctions are to be made in the context of component assemblies.

The term “between” may be employed in the context of the z-axis, x-axis or y-axis of a device. A material that is between two other materials may be in contact with one or both of those materials, or it may be separated from both of the other two materials by one or more intervening materials. A material “between” two other materials may therefore be in contact with either of the other two materials, or it may be coupled to the other two materials through an intervening material. A device that is between two other devices may be directly connected to one or both of those devices, or it may be separated from both of the other two devices by one or more intervening devices.

Here, multiple non-silicon semiconductor material layers may be stacked within a single fin structure. The multiple non-silicon semiconductor material layers may include one or more “P-type” layers that are suitable (e.g., offer higher hole mobility than silicon) for P-type transistors. The multiple non-silicon semiconductor material layers may further include one or more “N-type” layers that are suitable (e.g., offer higher electron mobility than silicon) for N-type transistors. The multiple non-silicon semiconductor material layers may further include one or more intervening layers separating the N-type from the P-type layers. The intervening layers may be at least partially sacrificial, for example to allow one or more of a gate, source, or drain to wrap completely around a channel region of one or more of the N-type and P-type transistors. The multiple non-silicon semiconductor material layers may be fabricated, at least in part, with self-aligned techniques such that a stacked CMOS device may include both a high-mobility N-type and P-type transistor with a footprint of a single finFET.

Here, the term “backend” generally refers to a section of a die which is opposite of a “frontend” and where an IC (integrated circuit) package couples to IC die bumps. For example, high-level metal layers (e.g., metal layer 6 and above in a ten-metal stack die) and corresponding vias that are closer to a die package are considered part of the backend of the die. Conversely, the term “frontend” generally refers to a section of the die that includes the active region (e.g., where transistors are fabricated) and low-level metal layers and corresponding vias that are closer to the active region (e.g., metal layer 5 and below in the ten-metal stack die example).

It is pointed out that those elements of the figures having the same reference numbers (or names) as the elements of any other figure can operate or function in any manner similar to that described, but are not limited to such.

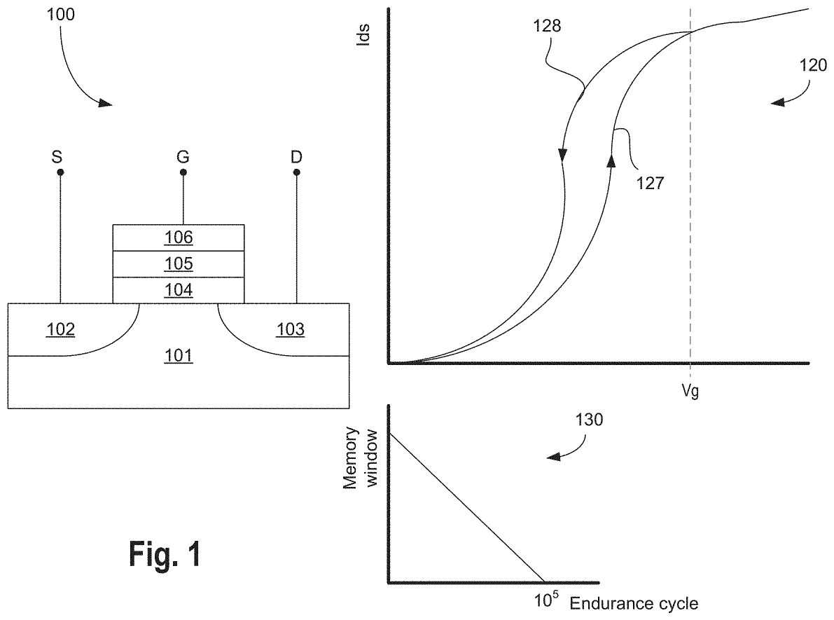

FIG. 1 illustrates a cross-section of FE transistor 100 (FE-FET) that suffers from high write energy and low endurance cycle. A typical FE transistor 100 comprises a gate (G) stack on substrate 101 positioned on either sides of source (S) 102 and drain (D) regions 103, where the gate stack includes an under-layer 104 (e.g., a dielectric), layer of FE material 105, and metal electrode 106. The Ids vs. Vgs transfer function of a typical FE transistor 100 is illustrated in plot 120, where waveforms 127 and 128 illustrates the memory window or memory behavior of the FE transistor. For higher electron/hole mobility under the gate stack, low-K dielectric is used for 104. However, low-k dielectric can easily break down when the voltage across the gate stack is about 3V or so, which is typical for gate voltage (Vg) to operate the FE transistor as a memory device. For example, to switch FE 105 between waveforms 127 and 128, Vg is typically at 3V. Such high Vg can break down dielectric 104, and is not sustainable for memories operating at low voltages (e.g., 1V or less). Plot 130 shows that to have a large memory window, large polarization is needed. However, operating the FE transistor at high voltages to achieve large memory window is desirable for low voltage products.

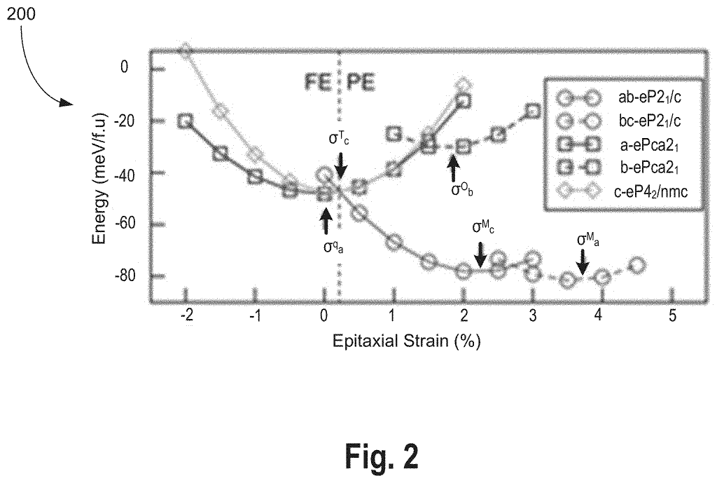

FIG. 2 illustrates plot 200 showing epitaxial strain for a FE material (e.g., ZrO2). Plot 200 shows that the polar orthorhombic phase, which contributes the ferroelectric response of the material, becomes more stable as the compressive epitaxial stress is applied to the material.

In some embodiments, a gate stack having FE material (or anti-FE material) adjacent to a dielectric (under-layer) is provided. A metal electrode is formed as the top layer of the gate stack. To improve the (anti-)ferroelectric response in the gate stack, misfit strain provided from the top metal electrode or bottom inter-layer (e.g., dielectric) or semiconductor is introduced. The misfit strain is determined by the lattice-mismatch between two adjacent layers (e.g., under-layer and the FE or anti-FE layer).

For perovskite crystals, the misfit strain effect is given in the following expressions:

$$\tilde{G} = {a}_{1}^{*} ( {P}_{1}^{2} + {P}_{2}^{2} ) + {a}_{3}^{*} {P}_{3}^{2} + {a}_{11}^{*} ( {P}_{1}^{4} + {P}_{2}^{4} ) + {a}_{33}^{*} {P}_{3}^{*} + {a}_{13}^{*} ( {P}_{1}^{2} {P}_{3}^{2} + {P}_{2}^{2} {P}_{3}^{2} ) + {a}_{12}^{*} {P}_{1}^{2} {P}_{2}^{2} + {a}_{111} ( {P}_{1}^{6} + {P}_{2}^{6} + {P}_{3}^{6} ) + {a}_{112} [ {P}_{1}^{4} ( {P}_{2}^{2} + {P}_{3}^{2} ) + {P}_{3}^{4} ( {P}_{1}^{2} + {P}_{2}^{2} ) + {P}_{2}^{4} ( {P}_{1}^{2} + {P}_{3}^{2} ) ] + {a}_{121} {P}_{1}^{2} {P}_{2}^{2} {P}_{3}^{2} + \frac{{u}_{m}^{2}}{{s}_{11} + {s}_{12}} ; \\ {a}_{1}^{*} = {a}_{1} - {u}_{m} \frac{{Q}_{11} + {Q}_{12}}{{s}_{11} + {s}_{12}} , {a}_{3}^{*} = {a}_{1} - {u}_{m} \frac{2 {Q}_{12}}{{s}_{11} + {s}_{12}} , \\ {a}_{11}^{*} = {a}_{11} + \frac{1}{2} \frac{1}{{s}_{11}^{2} - {s}_{12}^{2}} [ ( {Q}_{11}^{2} + {Q}_{12}^{2} ) {s}_{11} - 2 {Q}_{11} {Q}_{12} {s}_{12} ] , \\ {a}_{33}^{*} = {a}_{11} + \frac{{Q}_{12}^{2}}{{s}_{11} + {s}_{12}} , \\ {a}_{12}^{*} = {a}_{12} - \frac{1}{{s}_{11}^{2} - {s}_{12}^{2}} [ ( {Q}_{11}^{2} + {Q}_{12}^{2} ) {s}_{12} - 2 {Q}_{11} {Q}_{12} {s}_{11} ] + \frac{{Q}_{44}^{2}}{2 {s}_{44}} , \\ {a}_{13}^{*} = {a}_{12} + \frac{{Q}_{12} ( {Q}_{11} + {Q}_{12} )}{{s}_{11} + {s}_{12}} . \qquad ( 3 )$$

α*₁, α*₃, α*₁₁, α*₃₃, α*₁₂, α*₁₁₁, α*₁₁₂, and α*₁₂₃, are modified Landau expansion coefficients including spontaneous strain, μₘ the misfit strain, S₁₁, S₁₂, and S₄₄ are strain related coefficients, Q₁₁, Q₁₂, and Q₄₄ are coupling coefficients, and Pₓ, P_{y}, and P_{z} are polarization in the x, y, and z direction.

From the equation above, it is seen that tensile strain is required to improve the FE response in the gate stack, and the misfit strain is given as

μₘ=(b . . . α₀)/b

where b is the lattice constant of metal or inter-layer or semiconductor and α₀ is the lattice constant of FE oxide.

The above equations also show that for doped binary oxide (anti-)ferroelectric, compressive strain is required to improve the FE response. In addition, to improve the (anti-) FE response, the write voltage can be further reduced by increasing the electric field across the FE oxide based on following equation:

ρᵢₙₜ+ϵ_{DE}ϵ₀E_{DE}=ϵ₀E_{FE}+P

By assuming that there is no interfacial charge between (anti-)ferroelectric oxide and inter-layer, the electric field across (anti-)ferroelectric oxide increases with dielectric constant of inter-layer. Further, giant dielectric constant is obtained by ultra-thin (anti-)ferroelectric (e.g., less than 5 nm thickness).

In some embodiments, the gate stack comprises a first structure comprising a depolarized ferroelectric (FE) material (e.g., Si, La, N, Al, Zr, doped HfO2, perovskite FE such as BaTiO3, PbTiO3) or depolarized anti-FE material (e.g., Si, La, N, Al, Zr, doped HfO2, etc.). The first structure can be over a semiconductor material (e.g., Si, Ge, Ga, or As) which forms a channel region of the FE transistor. In some embodiments, the gate stack includes a second structure comprising strained FE material or a strained anti-FE material, wherein the second structure is over the first structure. A metal electrode (e.g., Ti, N, Si, Ta, Cu, Al, Au, W, or Co) is then formed adjacent to the second structure. In various embodiments, spacers are formed adjacent to either side of the gate stack. The material choice for the first and second structures provide lattice mismatch at the interface of the first and second structures. As such, tensile strain or compressive strain is provided within the gate stack to improve the response of the FE material. This strain (or strain engineering) allows the FE transistor having the gate stack to lower the switching voltage for the FE, which makes it more attractive for low voltage memory operation.

In some embodiments, the gate stack includes a high-K dielectric (under-layer) instead of a low-k dielectric as used by traditional FE gate stack of FIG. 1, wherein the high-K dielectric is adjacent to a strained FE or strained AFE material layer. Such a gate stack allows for reduced field across the dielectric, while allowing for lower switching voltage to switch the FE material. By strain engineering the gate stack, the write voltage is reduce (e.g., 1V or less), endurance cycle for memory operation is increased, and retention of data in the FE material is increased.

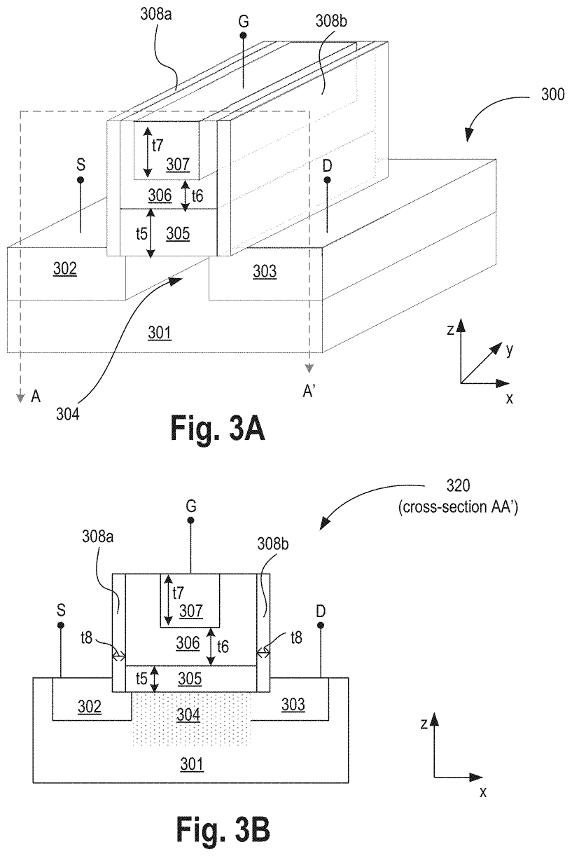

FIGS. 3A-B illustrate 3D view 300 and corresponding cross-sectional view 320, respectively, of a planar FE transistor with strained and depolarizing FE and/or anti-FE gate stack, where the depolarizing FE and/or anti-FE is adjacent to a channel region, in accordance with some embodiments.

Planar FET 300 comprises substrate 301, doped regions 302 and 303 forming source (S) and drain (D) regions, a gate (G) stack comprising a first structure 305 including an under-layer 305 having depolarized FE or depolarized anti-FE material; a second structure 306 including strained FE or strained FE; and gate metal layer 307; and spacers 308a/b. Here, channel region 304 comprises a semiconductor material for movement of holes and electrons.

In some embodiments, substrate 301 includes a suitable semiconductor material such as but not limited to, single crystal silicon, polycrystalline silicon and silicon on insulator (SOI). In another embodiment, substrate 301 includes other semiconductor materials such as germanium, silicon germanium, or a suitable group III-V or group III-N compound. The substrate 301 may also include semiconductor materials, metals, dopants, and other materials commonly found in semiconductor substrates. The semiconductor material for channel region 304 may have the same material as substrate 301, in accordance with some embodiments. In some embodiments, channel region 304 includes one of: Si, SiGe, Ge, and GaAs.

Gate under-layer 305 may include one layer or a stack of layers. In some embodiments, under-layer 305 comprises depolarized FE or depolarized anti-FE material. In some embodiments, the depolarized FE material includes Si, La, N, Al, Zr, doped HfO2, perovskite FE such as NH4H2PO4, KH2PO4, LiNbO3, LiTa03, BaTiO3, PbTiO3, Pb (Zr,Ti) O3, (Pb,La)TiO3, and (Pb,La)(Zr,Ti)O3. In some embodiments, anti-FE material includes one of more of: Si, La, N, Al, Zr, Ge, or Y doped HfO2. In some embodiments, depolarized FE material is a super-lattice. For example, super lattice of PbTiO₃ and SrTiO₃; super lattice of SrZrO₃ and BaZrO₃; Ca₃B₂O₇, where B is one of Mn or Ti or both; St₃B₂O₇, where B is one of Mn or Ti or both; NaRTiO₄, where R is one of Y, La, Na, Sm-Ho; super lattice YFeO₃ and YTiO₃; AMnO₃, where A is one of Tb or Y; Sr₃Zr₂O₇; CdCr₂O₄, etc. can be used for depolarized FE material 305. The thickness t5 of layer 305 in the z-direction is below 5 nm. In some embodiments, depolarized anti-FE material is used instead of depolarized FE material. In some embodiments, depolarized anti-FE material comprises one or more of: Si, La, N, Al, Zr, Ge, or Y doped HfO2. In some embodiments, the depolarizing ferroelectric and anti-ferroelectric material can be realized not only by thin ferroelectric and anti-ferroelectric layer but also by the ferroelectric and the dielectric in series.

In some embodiments, strained FE material 306 is deposited over gate under-layer 305. In some embodiments, strained FE material 306 includes one or more layers. In some embodiments, strained FE material includes: Si, La, N, Al, Zr, Ge, Y doped HfO2, perovskite ferroelectric such as NH4H2PO4, KH2PO4, LiNbO3, LiTa03, BaTiO3, PbTiO3, Pb (Zr,Ti) O3, (Pb,La)TiO3, and (Pb,La)(Zr,Ti)O3. In some embodiments, strained FE material 306 is a super-lattice. For example, super lattice of PbTiO₃ and SrTiO₃; super lattice of SrZrO₃ and BaZrO₃; Ca₃B2O₇, where B is one of Mn or Ti or both; St₃B2O₇, where B is one of Mn or Ti or both; NaRTiO₄, where R is one of Y, La, Na, Sm-Ho; super lattice YFeO₃ and YTiO₃; AMnO₃, where A is one of Tb or Y; Sr₃Zr₂O₇; CdCr₂O₄, etc. can be used for strained FE material 306. The thickness t6 of layer 306 in the z-direction is between 5 nm and 20 nm.

In some embodiments, gate metal layer 307 may comprise at least one P-type work-function metal or N-type work-function metal, depending on whether the transistor is to be a p-type or an n-type transistor. In some embodiments, gate metal layer 307 may comprise a stack of two or more metal layers, where one or more metal layers are work-function metal layers and at least one metal layer is a conductive fill layer. The thickness t7 for gate metal layer 307 in the z-direction is in a range of 10 nm to 20 nm.

For a p-type transistor, metals that are used for gate metal layer 307 include, but are not limited to, ruthenium, palladium, platinum, cobalt, nickel, and conductive metal oxides, e.g., ruthenium oxide. A p-type metal layer will enable the formation of p-type gate metal layer 307 with a work function that is between about 4.9 eV and about 5.2 eV. For a n-type transistor, metals that may be used for the gate metal layer 307 include, but are not limited to, hafnium, zirconium, titanium, tantalum, aluminum, alloys of these metals, and carbides of these metals such as hafnium carbide, zirconium carbide, titanium carbide, tantalum carbide, and aluminum carbide. An n-type metal layer will enable the formation of an n-type gate metal layer 307 with a work function that is between about 3.9 eV and about 4.2 eV.

In some embodiments, gate metal layer 307 includes a “U”-shaped structure that includes a bottom portion substantially parallel to the surface of the substrate and two sidewall portions that are substantially perpendicular to the top surface of the substrate. In another embodiment, at least one of the metal layers that form gate metal layer 307 may simply be a planar layer that is substantially parallel to the top surface of the substrate and does not include sidewall portions substantially perpendicular to the top surface of the substrate. In some embodiments, gate metal layer 307 includes a combination of U-shaped structures and planar, non-U-shaped structures.

For example, gate metal layer 307 includes of one or more U-shaped metal layers formed atop one or more planar, non-U-shaped layers. In some embodiments, metal of layer 307 includes one of: TiN, TiSiN, TaN, Cu, Al, Au, W, TiSiN, Co, Pt, or Ru. In some embodiments, metal of layer 307 includes one or more of: Ti, N, Si, Ta, Cu, Al, Au, W, or Co.

In some embodiments, pair of spacer layers (sidewall spacers) 308a/b are formed on opposing sides of the gate stack that bracket the gate stack. The pair of spacer layers 308a/b are formed from a material such as silicon nitride, silicon oxide, silicon carbide, silicon nitride doped with carbon, and silicon oxynitride. Processes for forming sidewall spacers are well-known in the art and generally include deposition and etching process operations. In some embodiments, a plurality of spacer pairs may be used, for instance, two pairs, three pairs, or four pairs of sidewall spacers may be formed on opposing sides of the gate stack. The thickness t8 of spacers 308a/b is in a rage of 20 nm and 100 nm. The height of spacers 308a/b along the z-axis is between 5 nm and 50 nm.

In some embodiments, source region 302 and drain region 303 are formed within substrate 301 adjacent to the gate stack of the transistor. Source region 302 and drain region 303 are generally formed using either an implantation/diffusion process or an etching/deposition process. In the former process, dopants such as boron, aluminum, antimony, phosphorous, or arsenic may be ion-implanted into the substrate to form source region 302 and drain region 303. An annealing process that activates the dopants and causes them to diffuse further into the substrate typically follows the ion-implantation process. In the latter process, the substrate may first be etched to form recesses at the locations of the source and drain regions. An epitaxial deposition process may then be carried out to fill the recesses with material that is used to fabricate source region 302 and drain region 303. In some embodiments, source region 302 and drain region 303 are fabricated using a silicon alloy such as silicon germanium or silicon carbide. In some embodiments, the epitaxially deposited silicon alloy is doped in-situ with dopants such as boron, arsenic, or phosphorous. In some embodiments, source region 302 and drain region 303 are formed using one or more alternate semiconductor materials such as germanium or a suitable group III-V compound. In some embodiments, one or more layers of metal and/or metal alloys are used to form the source region 302 and drain region 303.

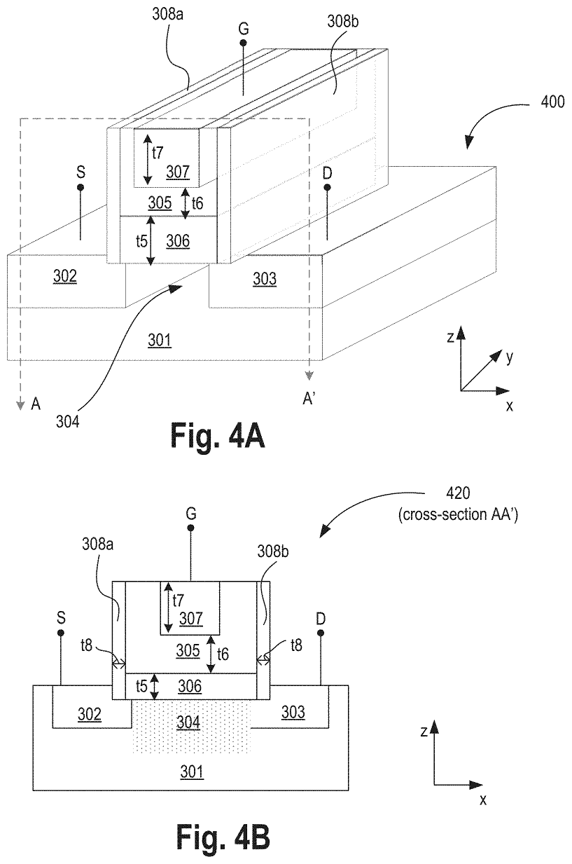

FIGS. 4A-B illustrate 3D view 400 and corresponding cross-sectional view 420, respectively, of a planar FE transistor with strained and depolarizing FE and/or anti-FE gate stack, where the strained FE and/or anti-FE is adjacent to a channel region, in accordance with some embodiments. Compared to FIGS. 3A-B, here positions for layers 305 and 306 are switched. For example, layer 305, which was adjacent to semiconductor region 304, is now over layer 306, while layer 306 is not adjacent to the semiconductor region 304. Operation and technical effect wise, FETs of FIGS. 3A-B are similar to the FETs of FIGS. 4A-B.

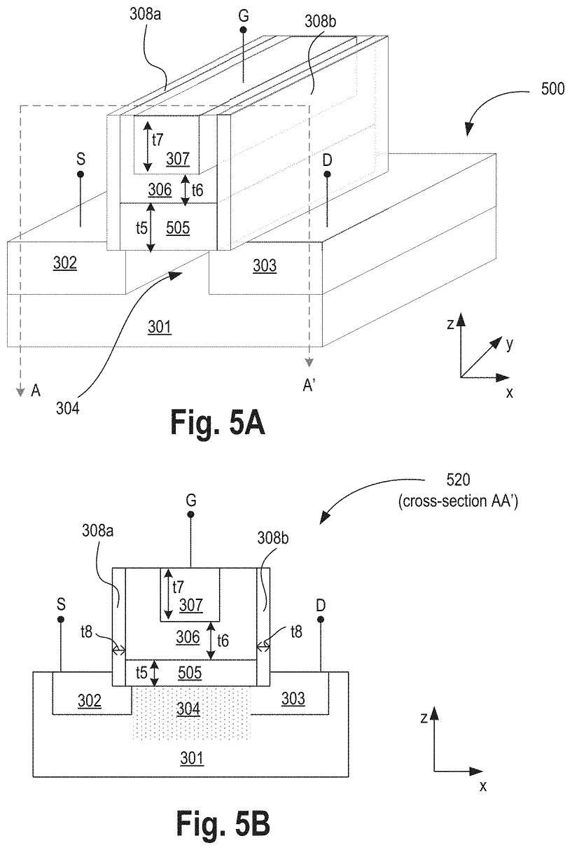

FIGS. 5A-B illustrate 3D view 500 and corresponding cross-sectional view 520, respectively, of a planar FE transistor with strained FE and/or anti-FE and high-K dielectric gate stack, where the high-K dielectric is adjacent to a channel region, in accordance with some embodiments. Compared to FIGS. 5A-B, here positions layer 305 is replaced with high-K dielectric under-layer 505. In some embodiments, high-K dielectric 505 includes one of: SiO2, Al2O3, HfO2, Ta2O3, and/or La2O3. In some embodiments, when atomic layer deposition (ALD) is used to grow the oxide, doped HfO2 can be realized in the form of super-lattice. In some embodiments, high-K dielectric includes one layer or a stack of layers. The one or more layers may include silicon oxide, silicon dioxide (SiO₂) and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process is carried out on gate dielectric layer 505 to improve its quality when a high-k material is used. The thickness t5 of the dielectric layer 505 in the z-direction is in the range of 5 to 20 Angstrom. In some embodiments, thickness t5 of dielectric layer 505 is below 3 nm.

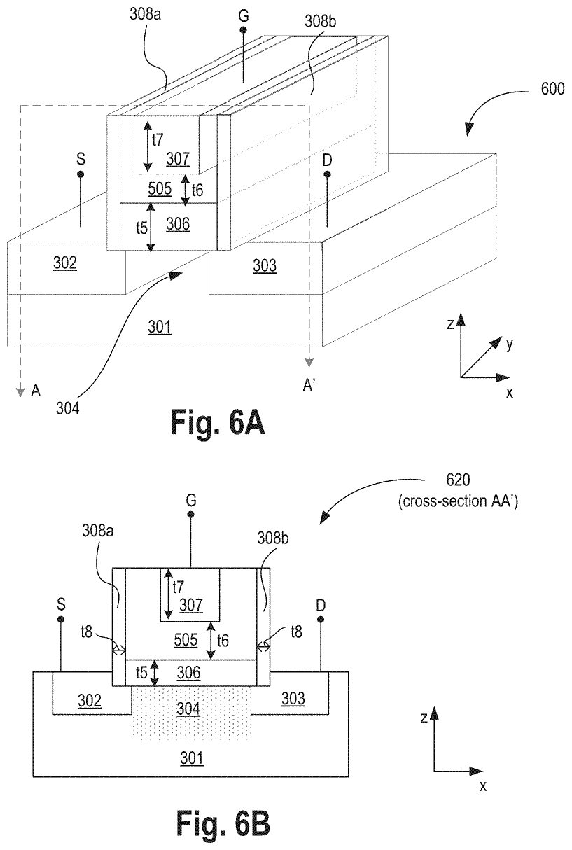

FIGS. 6A-B illustrate 3D view 600 and corresponding cross-sectional view 620, respectively, of a planar FE transistor with strained FE and/or anti-FE and high-K dielectric gate stack, where the strained FE and/or anti-FE is adjacent to a channel region, in accordance with some embodiments. Compared to FIGS. 3A-B, here positions for layers 505 and 306 are switched. For example, layer 505, which was adjacent to semiconductor region 304, is now over layer 306, while layer 306 is not adjacent to the semiconductor region 304. Operation and technical effect wise, FETs of FIGS. 6A-B are similar to the FETs of FIGS. 5A-B.

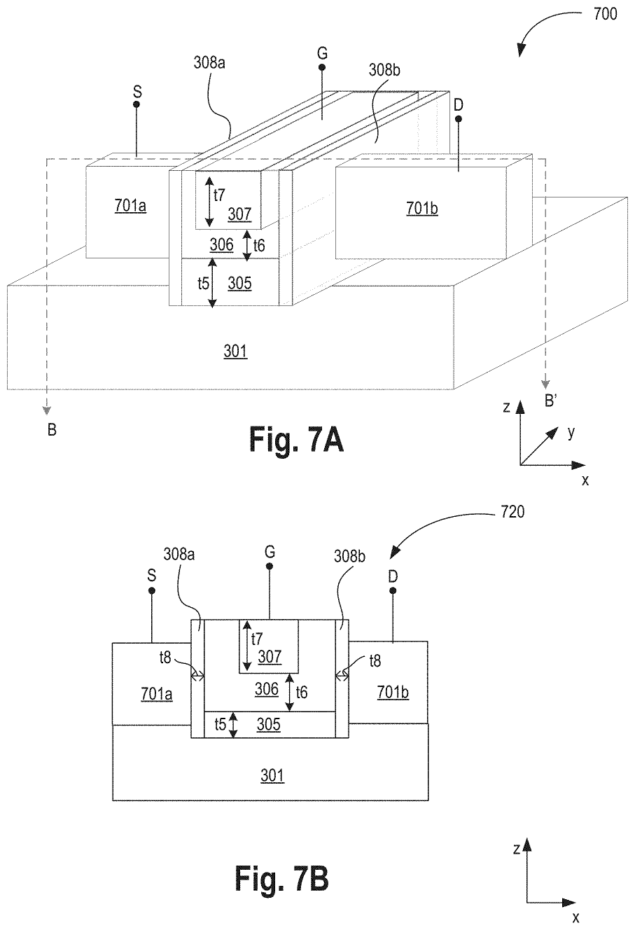

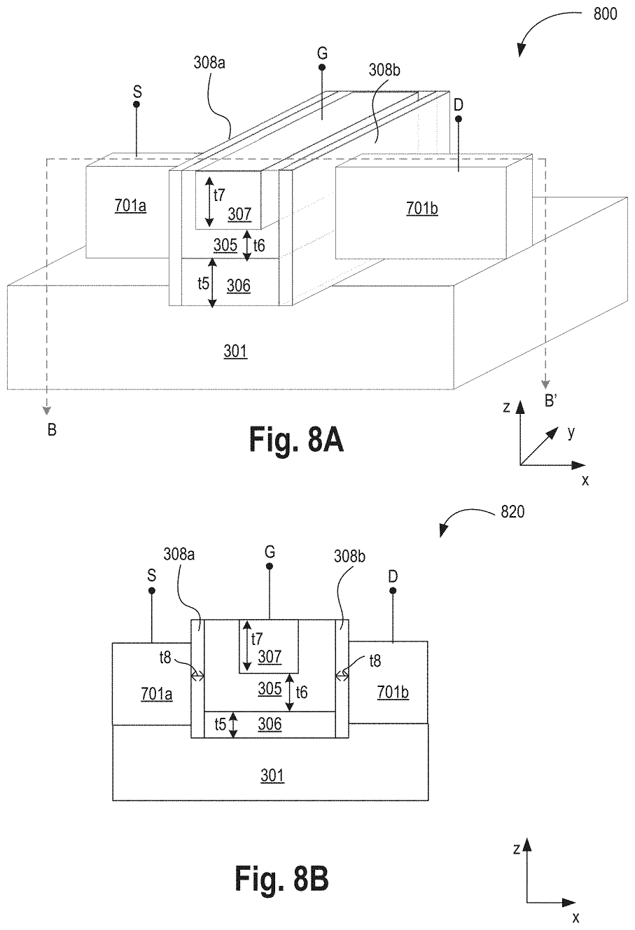

FIGS. 7A-B illustrate 3D view 700 and corresponding cross-sectional view 720, respectively, of a finFET FE transistor with strained and depolarizing FE and/or anti-FE gate stack, where the depolarizing FE and/or anti-FE is adjacent to a channel region, in accordance with some embodiments. FinFET is an example of a non-planar transistor. FinFET comprises a fin that includes source (S) 701a and drain (D) 701b regions, and a channel between the source and regions. Transistor 700 can have multiple fins parallel to one another that are coupled to the same gate stack. The fins pass through the gate stack forming source and drain regions. The gate stack for FinFET of FIG. 8A is similar as that of the gate stack of planar transistor of FIG. 3A and conformed for FinFET process.

FIGS. 8A-B illustrate 3D view 800 and corresponding cross-sectional view 820, respectively, of a finFET FE transistor with strained and depolarizing FE and/or anti-FE gate stack, where the strained FE and/or anti-FE is adjacent to a channel region, in accordance with some embodiments. Compared to FIGS. 7A-B, here positions for layers 305 and 306 are switched. For example, layer 305 which was adjacent to semiconductor region 304 is now over layer 306, while layer 306 is not adjacent to the semiconductor region 304. Operation and technical effect wise, FETs of FIGS. 8A-B are similar to the FETs of FIGS. 7A-B.

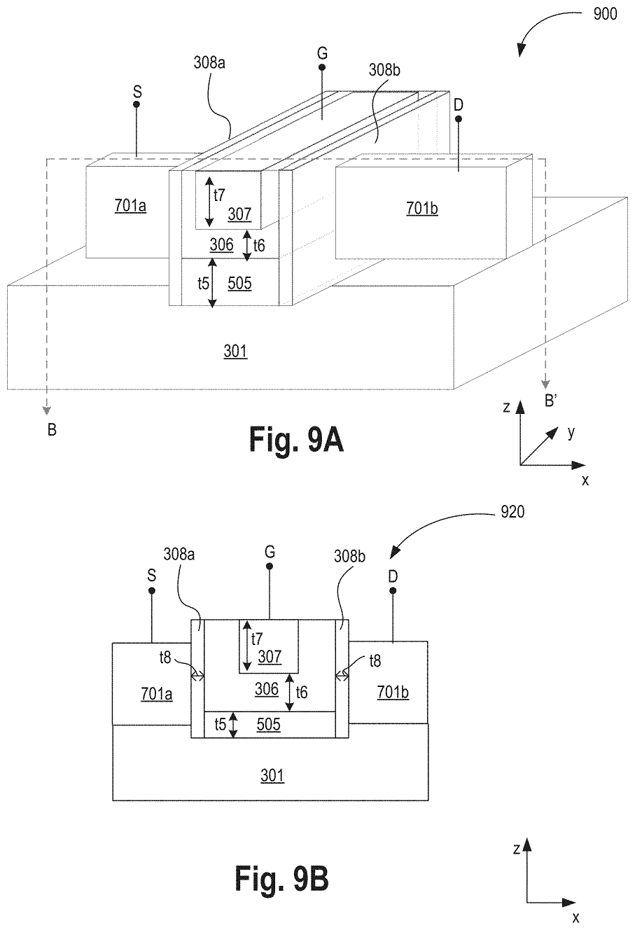

FIGS. 9A-B illustrate 3D view 900 and corresponding cross-sectional view 920, respectively, of a finFET FE transistor with strained FE and/or anti-FE and high-K dielectric gate stack, where the high-K dielectric is adjacent to a channel region, in accordance with some embodiments. Compared to FIGS. 9A-B, here positions layer 305 is replaced with high-K dielectric under-layer 505. In some embodiments, the high-K dielectric includes one of: SiO2, AlO2, HfO2, or ZrO2. In some embodiments, high-K dielectric includes one layer or a stack of layers. The one or more layers may include silicon oxide, silicon dioxide (SiO₂) and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and zinc. Examples of high-k materials that may be used in the gate dielectric layer include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and lead zinc niobate. In some embodiments, an annealing process is carried out on the gate dielectric layer 505 to improve its quality when a high-k material is used. The thickness t5 of the dielectric layer 505 in the z-direction is in the range of 5 to 20 Angstrom. In some embodiments, thickness t5 of dielectric layer 505 is below 3 nm.

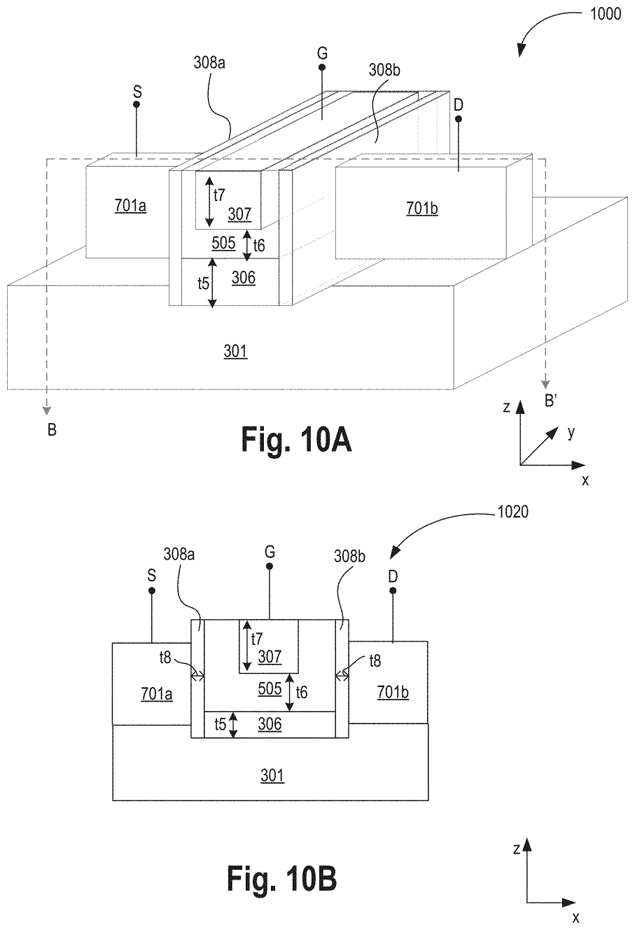

FIGS. 10A-B illustrate 3D view 1000 and corresponding cross-sectional view 1020, respectively, of a finFET FE transistor with strained FE and/or anti-FE and high-K dielectric gate stack, where the strained FE and/or anti-FE is adjacent to a channel region, in accordance with some embodiments. Compared to FIGS. 10A-B, here positions for layers 505 and 306 are switched. For example, layer 505, which was adjacent to semiconductor region 301, is now over layer 306, while layer 306 is not adjacent to the semiconductor region 301. Operation and technical effect wise, FETs of FIGS. 6A-B are similar to the FETs of FIGS. 5A-B.

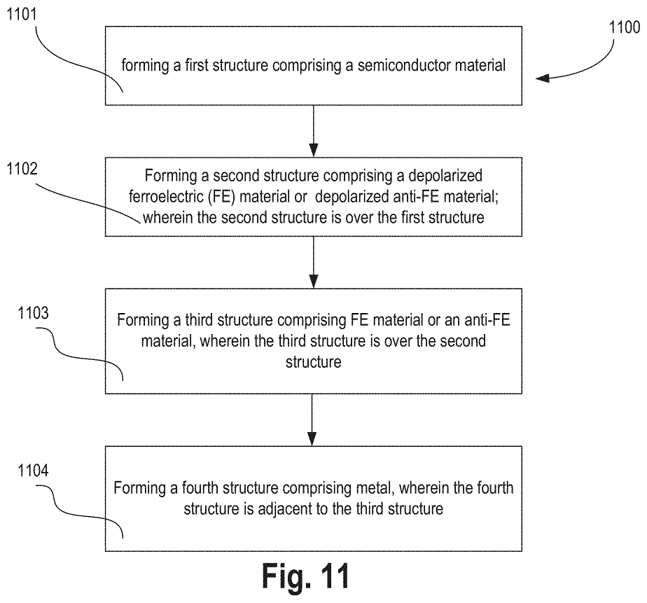

FIG. 11 illustrates flowchart 1100 of a method for forming a gate stack for a transistor, wherein the gate stack includes strained and depolarizing FE or anti-FE, in accordance with some embodiments. A similar process can also be used to form an FE transistor with strained FE or strained anti-FE coupled to a high-k dielectric. While the following blocks (or process operations) in the flowchart are arranged in a certain order, the order can be changed. In some embodiments, some blocks can be executed in parallel.

At block 1101, a first structure is formed comprising a semiconductor material. In some embodiments, the semiconductor material includes one or more of: Si, Ge, Ga, or As.

At block 1102, a second structure is formed comprising a depolarized ferroelectric (FE) material or depolarized anti-FE material; wherein the second structure is over the first structure. In some embodiments, the second structure has a thickness between 5 Angstroms and 50 Angstroms. In some embodiments, the thickness of the second structure is below 5 nm.

At block 1103, a third structure is formed comprising FE material or an anti-FE material, wherein the third structure is over the second structure. In some embodiments, the FE material or the anti-FE material of the third structure comprises strained FE material or strained anti-FE material. In some embodiments, the third structure has a thickness in a range of 10 Angstroms to 20 Angstroms. In some embodiments, a thickness of the third structure is in a range of 4 nm to 20 nm. In some embodiments, the ferroelectric material of the third structure includes one or more of: Pb, Ti, Zr, Ba, N Si, La, Al, or Hf. In some embodiments, the anti-ferroelectric material of the third structure includes one or more of: Si, La, N, Al, Zr, or Hf.

At block 1104, a fourth structure is formed comprising metal, wherein the fourth structure is adjacent to the third structure. In some embodiments, the metal of the fourth structure comprises one or more of: Ti, N, Si, Ta, Cu, Al, Au, W, or Co. In some embodiments, the method further comprises forming a first spacer and a second spacer, wherein the first and second spacers are adjacent to the second and third structures.

In some embodiments, the first, second, third, and fourth structures are part of a gate stack of a transistor, wherein the transistor is one of a planar transistor, fin field effect transistor, or nanowire transistor.

In some embodiments, the method for forming the FE FET comprises: forming a substrate followed by forming a source and drain adjacent to the substrate. In various embodiments, a semiconductor body is formed between the source and drain. In some embodiments, a gate stack is formed between the source and drain. Forming the gate stack includes: forming a first structure comprising a high K dielectric; a second structure comprising strained ferroelectric (FE) material or strained anti-FE material, wherein the second structure is adjacent to the first structure; and a third structure comprising metal. In some embodiments, first and second spacers on either side of the gate stack and adjacent to the gate stack, wherein the first spacer is further adjacent to the source, and wherein the second spacer is further adjacent to the drain. In some embodiments, the strained FE material of the second structure comprises one or more of: Pb, Ti, Zr, Ba, N Si, La, Al, or Hf. In some embodiments, the strained anti-FE material of the second structure comprises one or more of: Si, La, N, Al, Zr, or Hf. In some embodiments, the high K dielectric includes one or more of: Si, Al, Hf, or Zr. In some embodiments, the first structure has a thickness in a range of 5 A to 20 A; and the second structure has a thickness in a range of 10 A to 18 A.

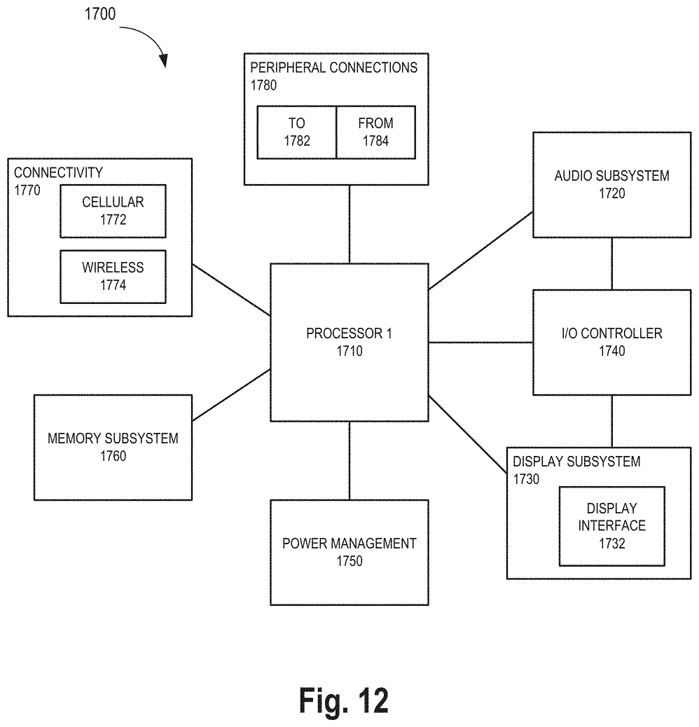

FIG. 12 illustrates a smart device, a computer system, or a SoC (System-on-Chip) with strained and depolarizing FE or anti-FE gate stack or with strained FE or strained anti-FE gate stack with high-K dielectric, according to some embodiments of the disclosure. FIG. 12 illustrates a block diagram of an embodiment of a mobile device in which flat surface interface connectors could be used. In some embodiments, computing device 1700 represents a mobile computing device, such as a computing tablet, a mobile phone or smart-phone, a wireless-enabled e-reader, or other wireless mobile device. It will be understood that certain components are shown generally, and not all components of such a device are shown in computing device 1700.

In some embodiments, computing device 1700 includes first processor 1710 with strained and depolarizing FE or anti-FE gate stack, according to some embodiments discussed. In some embodiments, the gate stack includes strained FE or anti-FE material adjacent to a high-K dielectric. Other blocks of the computing device 1700 may also include strained and depolarizing FE or anti-FE gate stack or a gate stack, which includes strained FE or anti-FE material adjacent to a high-K dielectric, according to some embodiments. The various embodiments of the present disclosure may also comprise a network interface within 1770 such as a wireless interface so that a system embodiment may be incorporated into a wireless device, for example, cell phone or personal digital assistant.

In some embodiments, processor 1710 can include one or more physical devices, such as microprocessors, application processors, microcontrollers, programmable logic devices, or other processing means. The processing operations performed by processor 1710 include the execution of an operating platform or operating system on which applications and/or device functions are executed. The processing operations include operations related to 1/0 (input/output) with a human user or with other devices, operations related to power management, and/or operations related to connecting the computing device 1700 to another device. The processing operations may also include operations related to audio I/O and/or display I/O.

In some embodiments, computing device 1700 includes audio subsystem 1720, which represents hardware (e.g., audio hardware and audio circuits) and software (e.g., drivers, codecs) components associated with providing audio functions to the computing device. Audio functions can include speaker and/or headphone output, as well as microphone input. Devices for such functions can be integrated into computing device 1700, or connected to the computing device 1700. In one embodiment, a user interacts with the computing device 1700 by providing audio commands that are received and processed by processor 1710.

In some embodiments, computing device 1700 comprises display subsystem 1730. Display subsystem 1730 represents hardware (e.g., display devices) and software (e.g., drivers) components that provide a visual and/or tactile display for a user to interact with the computing device 1700. Display subsystem 1730 includes display interface 1732, which includes the particular screen or hardware device used to provide a display to a user. In one embodiment, display interface 1732 includes logic separate from processor 1710 to perform at least some processing related to the display. In one embodiment, display subsystem 1730 includes a touch screen (or touch pad) device that provides both output and input to a user.

In some embodiments, computing device 1700 comprises I/O controller 1740. I/O controller 1740 represents hardware devices and software components related to interaction with a user. I/O controller 1740 is operable to manage hardware that is part of audio subsystem 1720 and/or display subsystem 1730. Additionally, I/O controller 1740 illustrates a connection point for additional devices that connect to computing device 1700 through which a user might interact with the system. For example, devices that can be attached to the computing device 1700 might include microphone devices, speaker or stereo systems, video systems or other display devices, keyboard or keypad devices, or other I/O devices for use with specific applications such as card readers or other devices.

As mentioned above, I/O controller 1740 can interact with audio subsystem 1720 and/or display subsystem 1730. For example, input through a microphone or other audio device can provide input or commands for one or more applications or functions of the computing device 1700. Additionally, audio output can be provided instead of, or in addition to display output. In another example, if display subsystem 1730 includes a touch screen, the display device also acts as an input device, which can be at least partially managed by I/O controller 1740. There can also be additional buttons or switches on the computing device 1700 to provide I/O functions managed by I/O controller 1740.

In some embodiments, I/O controller 1740 manages devices such as accelerometers, cameras, light sensors or other environmental sensors, or other hardware that can be included in the computing device 1700. The input can be part of direct user interaction, as well as providing environmental input to the system to influence its operations (such as filtering for noise, adjusting displays for brightness detection, applying a flash for a camera, or other features).

In some embodiments, computing device 1700 includes power management 1750 that manages battery power usage, charging of the battery, and features related to power saving operation. Memory subsystem 1760 includes memory devices for storing information in computing device 1700. Memory can include nonvolatile (state does not change if power to the memory device is interrupted) and/or volatile (state is indeterminate if power to the memory device is interrupted) memory devices. Memory subsystem 1760 can store application data, user data, music, photos, documents, or other data, as well as system data (whether long-term or temporary) related to the execution of the applications and functions of the computing device 1700.

Elements of embodiments are also provided as a machine-readable medium (e.g., memory 1760) for storing the computer-executable instructions (e.g., instructions to implement any other processes discussed herein). The machine-readable medium (e.g., memory 1760) may include, but is not limited to, flash memory, optical disks, CD-ROMs, DVD ROMs, RAMs, EPROMs, EEPROMs, magnetic or optical cards, phase change memory (PCM), or other types of machine-readable media suitable for storing electronic or computer-executable instructions. For example, embodiments of the disclosure may be downloaded as a computer program (e.g., BIOS) which may be transferred from a remote computer (e.g., a server) to a requesting computer (e.g., a client) by way of data signals via a communication link (e.g., a modem or network connection).

In some embodiments, computing device 1700 comprises connectivity 1770. Connectivity 1770 includes hardware devices (e.g., wireless and/or wired connectors and communication hardware) and software components (e.g., drivers, protocol stacks) to enable the computing device 1700 to communicate with external devices. The computing device 1700 could be separate devices, such as other computing devices, wireless access points or base stations, as well as peripherals such as headsets, printers, or other devices.

Connectivity 1770 can include multiple different types of connectivity. To generalize, the computing device 1700 is illustrated with cellular connectivity 1772 and wireless connectivity 1774. Cellular connectivity 1772 refers generally to cellular network connectivity provided by wireless carriers, such as provided via GSM (global system for mobile communications) or variations or derivatives, CDMA (code division multiple access) or variations or derivatives, TDM (time division multiplexing) or variations or derivatives, or other cellular service standards. Wireless connectivity (or wireless interface) 1774 refers to wireless connectivity that is not cellular, and can include personal area networks (such as Bluetooth, Near Field, etc.), local area networks (such as Wi-Fi), and/or wide area networks (such as WiMax), or other wireless communication.

In some embodiments, computing device 1700 comprises peripheral connections 1780. Peripheral connections 1780 include hardware interfaces and connectors, as well as software components (e.g., drivers, protocol stacks) to make peripheral connections. It will be understood that the computing device 1700 could both be a peripheral device (“to” 1782) to other computing devices, as well as have peripheral devices (“from” 1784) connected to it. The computing device 1700 commonly has a “docking” connector to connect to other computing devices for purposes such as managing (e.g., downloading and/or uploading, changing, synchronizing) content on computing device 1700. Additionally, a docking connector can allow computing device 1700 to connect to certain peripherals that allow the computing device 1700 to control content output, for example, to audiovisual or other systems.

In addition to a proprietary docking connector or other proprietary connection hardware, the computing device 1700 can make peripheral connections 1780 via common or standards-based connectors. Common types can include a Universal Serial Bus (USB) connector (which can include any of a number of different hardware interfaces), DisplayPort including MiniDisplayPort (MDP), High Definition Multimedia Interface (HDMI), Firewire, or other types.

Reference in the specification to “an embodiment,” “one embodiment,” “some embodiments,” or “other embodiments” means that a particular feature, structure, or characteristic described in connection with the embodiments is included in at least some embodiments, but not necessarily all embodiments. The various appearances of “an embodiment,” “one embodiment,” or “some embodiments” are not necessarily all referring to the same embodiments. If the specification states a component, feature, structure, or characteristic “may,” “might,” or “could” be included, that particular component, feature, structure, or characteristic is not required to be included. If the specification or claim refers to “a” or “an” element, that does not mean there is only one of the elements. If the specification or claims refer to “an additional” element, that does not preclude there being more than one of the additional element.

Furthermore, the particular features, structures, functions, or characteristics may be combined in any suitable manner in one or more embodiments. For example, a first embodiment may be combined with a second embodiment anywhere the particular features, structures, functions, or characteristics associated with the two embodiments are not mutually exclusive.

While the disclosure has been described in conjunction with specific embodiments thereof, many alternatives, modifications and variations of such embodiments will be apparent to those of ordinary skill in the art in light of the foregoing description. The embodiments of the disclosure are intended to embrace all such alternatives, modifications, and variations as to fall within the broad scope of the appended claims.

In addition, well known power/ground connections to integrated circuit (IC) chips and other components may or may not be shown within the presented figures, for simplicity of illustration and discussion, and so as not to obscure the disclosure. Further, arrangements may be shown in block diagram form in order to avoid obscuring the disclosure, and also in view of the fact that specifics with respect to implementation of such block diagram arrangements are highly dependent upon the platform within which the present disclosure is to be implemented (i.e., such specifics should be well within purview of one skilled in the art). Where specific details (e.g., circuits) are set forth in order to describe example embodiments of the disclosure, it should be apparent to one skilled in the art that the disclosure can be practiced without, or with variation of, these specific details. The description is thus to be regarded as illustrative instead of limiting.

Following examples illustrates the various embodiments. The examples can be combined in any suitable order.

Example 1: An apparatus comprising: a first structure comprising a semiconductor material; a second structure comprising a depolarized ferroelectric (FE) material or depolarized anti-FE material; wherein the second structure is over the first structure; a third structure comprising FE material or an anti-FE material, wherein the third structure is over the second structure; and a fourth structure comprising metal, wherein the fourth structure is adjacent to the third structure.

Example 2: The apparatus of example 1, wherein the FE material or the anti-FE material of the third structure comprises strained FE material or strained anti-FE material.

Example 3: The apparatus of example 1, wherein the third structure has a thickness in a range of 10 Angstroms to 19 Angstroms.

Example 4: The apparatus of example 1, wherein the second structure has a thickness between 5 Angstroms and 50 Angstroms.

Example 5: The apparatus of example 1, wherein a thickness of the third structure is in a range of 4 nm to 20 nm.

Example 6: The apparatus of example 1, wherein a thickness of the second structure is below 5 nm.

Example 7: The apparatus of example 1, wherein the metal of the fourth structure comprises one or more of: Ti, N, Si, Ta, Cu, Al, Au, W, Co, Pt, or Ru.

Example 8: The apparatus of example 1, wherein the semiconductor material includes one or more of: Si, Ge, Ga, or As.

Example 9: The apparatus of example 1, wherein the ferroelectric material of the third structure includes one or more of: Pb, Ti, Zr, Ba, N Si, La, Al, Y, Hf, H, P, Nb, Li, or Ta.

Example 10: The apparatus of example 1, wherein the anti-ferroelectric material of the third structure includes one or more of: Pb, Ti, Zr, Ba, N Si, La, Al, Y, Hf, H, P, Nb, Li, or Ta.

Example 11: The apparatus of example 1, wherein the first, second, third, and fourth structures are part of a gate stack of a transistor, wherein the transistor is one of a planar transistor, fin field effect transistor, or nanowire transistor.

Example 12: The apparatus of example 1 comprising a first spacer and a second spacer, wherein the first and second spacers are adjacent to the second and third structures.

Example 13: A field effect transistor (FET) comprising: a substrate; a source and drain adjacent to the substrate; a semiconductor body between the source and drain; a gate stack between the source and drain, wherein the gate stack includes: a first structure comprising a high K dielectric; a second structure comprising strained ferroelectric (FE) material or strained anti-FE material, wherein the second structure is adjacent to the first structure; and a third structure comprising metal; and first and second spacers on either side of the gate stack and adjacent to the gate stack, wherein the first spacer is further adjacent to the source, and wherein the second spacer is further adjacent to the drain.

Example 14: The FET of example 13, wherein the strained FE material of the second structure comprises one or more of: Pb, Ti, Zr, Ba, N Si, La, Al, Y, Hf, H, P, Nb, Li, or Ta.

Example 15: The FET of example 13, wherein the strained anti-FE material of the second structure comprises one or more of: Si, La, N, Al, Zr, or Hf.

Example 16: The FET of example 13, wherein the high K dielectric includes one or more of: Si, Al, Hf, Ta, La, or Zr.

Example 17: The FET of example 13, wherein: the first structure has a thickness in a range of 5 A to 20 A; and the second structure has a thickness in a range of 10 A to 18 A.

Example 18: A system comprising: a memory; a processor coupled to the memory, the processor including a transistor having a gate stack comprising an apparatus according to any one of examples 8 to 12; and a wireless interface to allow the processor to communicate with another device.

Example 19: A system comprising: a memory; a processor coupled to the memory, the processor including a transistor having a gate stack comprising an apparatus according to any one of examples 13 to 17; and a wireless interface to allow the processor to communicate with another device.

Example 20: A method comprising: forming a first structure comprising a semiconductor material; forming a second structure comprising a depolarized ferroelectric (FE) material or depolarized anti-FE material; wherein the second structure is over the first structure; forming a third structure comprising FE material or an anti-FE material, wherein the third structure is over the second structure; and forming a fourth structure comprising metal, wherein the fourth structure is adjacent to the third structure.

Example 21: The method of example 20, wherein the FE material or the anti-FE material of the third structure comprises strained FE material or strained anti-FE material.

Example 22: The method of example 20, wherein the third structure has a thickness in a range of 10 Angstroms to 19 Angstroms.

Example 23: The method of example 20, wherein the second structure has a thickness between 5 Angstroms and 50 Angstroms.

Example 24: The method of example 20, wherein a thickness of the third structure is in a range of 4 nm to 20 nm.

Example 25: The method of example 20, wherein a thickness of the second structure is below 5 nm.

Example 26: The method of example 20, wherein the metal of the fourth structure comprises one or more of: Ti, N, Si, Ta, Cu, Al, Au, W, Co, Pt, or Ru.

Example 27: The method of example 20, wherein the semiconductor material includes one or more of: Si, Ge, Ga, or As.

Example 28: The method of example 20, wherein the ferroelectric material of the third structure includes one or more of: Pb, Ti, Zr, Ba, N Si, La, Al, Y, Hf, H, P, Nb, Li, or Ta.

Example 29: The method of example 20, wherein the anti-ferroelectric material of the third structure includes one or more of: Pb, Ti, Zr, Ba, N Si, La, Al, Y, Hf, H, P, Nb, Li, or Ta.

Example 30: The method of method 20, wherein the first, second, third, and fourth structures are part of a gate stack of a transistor, wherein the transistor is one of a planar transistor, fin field effect transistor, or nanowire transistor.

Example 31: The method of example 20 comprising forming a first spacer and a second spacer, wherein the first and second spacers are adjacent to the second and third structures.

Example 32: A method for forming a field effect transistor (FET) comprising: forming a substrate; forming a source and drain adjacent to the substrate; forming a semiconductor body between the source and drain; forming a gate stack between the source and drain, wherein forming the gate stack includes: forming a first structure comprising a high K dielectric; forming a second structure comprising strained ferroelectric (FE) material or strained anti-FE material, wherein the second structure is adjacent to the first structure; and forming a third structure comprising metal; and first and second spacers on either side of the gate stack and adjacent to the gate stack, wherein the first spacer is further adjacent to the source, and wherein the second spacer is further adjacent to the drain.

Example 33: The method of example 32, wherein the strained FE material of the second structure comprises one or more of: Pb, Ti, Zr, Ba, N Si, La, Al, Y, Hf, H, P, Nb, Li, or Ta.

Example 34: The method of example 32, wherein the strained anti-FE material of the second structure comprises one or more of: Si, La, N, Al, Zr, or Hf.

Example 35: The method of example 32, wherein the high K dielectric includes one or more of: Si, Al, Hf, Ta, La, or Zr.

Example 36: The method of example 32, wherein: the first structure has a thickness in a range of 5 A to 20 A; and the second structure has a thickness in a range of 10 A to 18 A.

An abstract is provided that will allow the reader to ascertain the nature and gist of the technical disclosure. The abstract is submitted with the understanding that it will not be used to limit the scope or meaning of the claims. The following claims are hereby incorporated into the detailed description, with each claim standing on its own as a separate embodiment.

We claim:

1. An apparatus comprising:
a first structure comprising a semiconductor material;
a second structure comprising a depolarized ferroelectric (FE) material or depolarized anti-FE material; wherein the second structure is over the first structure;
a third structure comprising FE material or an anti-FE material, wherein the third structure is over the second structure; and
a fourth structure comprising metal, wherein the fourth structure is adjacent to the third structure.

2. The apparatus of claim 1, wherein the FE material or the anti-FE material of the third structure comprises strained FE material or strained anti-FE material.

3. The apparatus of claim 1, wherein the third structure has a thickness in a range of 10 Angstroms to 19 Angstroms.

4. The apparatus of claim 1, wherein the second structure has a thickness between 5 Angstroms and 50 Angstroms.

5. The apparatus of claim 1, wherein a thickness of the third structure is in a range of 4 nm to 20 nm.

6. The apparatus of claim 1, wherein a thickness of the second structure is below 5 nm.

7. The apparatus of claim 1, wherein the metal of the fourth structure comprises one or more of: Ti, N, Si, Ta, Cu, Al, Au, W, Co, Pt, or Ru.

8. The apparatus of claim 1, wherein the semiconductor material includes one or more of:
Si, Ge, Ga, or As.

9. The apparatus of claim 1, wherein the ferroelectric material of the third structure includes one or more of: Pb, Ti, Zr, Ba, N Si, La, Al, Y, Hf, H, P, Nb, Li, or Ta.

10. The apparatus of claim 1, wherein the anti-ferroelectric material of the third structure includes one or more of: Pb, Ti, Zr, Ba, N Si, La, Al, Y, Hf, H, P, Nb, Li, or Ta.

11. The apparatus of claim 1, wherein the first, second, third, and fourth structures are part of a gate stack of a transistor, wherein the transistor is one of a planar transistor, fin field effect transistor, or nanowire transistor.

12. The apparatus of claim 1 comprising a first spacer and a second spacer, wherein the first and second spacers are adjacent to the second and third structures.

13. A field effect transistor (FET) comprising:
a substrate;
a source and drain adjacent to the substrate;
a semiconductor body between the source and drain;
a gate stack between the source and drain, wherein the gate stack includes:
a first structure comprising a high K dielectric;
a second structure comprising strained ferroelectric (FE) material or strained anti-FE material, wherein the second structure is adjacent to the first structure; and
a third structure comprising metal; and
first and second spacers on either side of the gate stack and adjacent to the gate stack, wherein the first spacer is adjacent to the source, and wherein the second spacer is adjacent to the drain.

14. The FET of claim 13, wherein the strained FE material of the second structure includes one or more of: Pb, Ti, Zr, Ba, N Si, La, Al, Y, Hf, H, P, Nb, Li, or Ta.

15. The FET of claim 13, wherein the strained anti-FE material of the second structure includes one or more of: Si, La, N, Al, Zr, or Hf.

16. The FET of claim 13, wherein the high K dielectric includes one or more of: Si, Al, Hf, Ta, La, or Zr.

17. The FET of claim 13, wherein:
the first structure has a thickness in a range of 5 A to 20 A; and
the second structure has a thickness in a range of 10 A to 18 A.

18. A system comprising:
a memory;
a processor coupled to the memory, the processor including a transistor having a gate stack comprising:
a first structure comprising a semiconductor material;
a second structure comprising a depolarized ferroelectric (FE) material or depolarized anti-FE material; wherein the second structure is over the first structure;
a third structure comprising FE material or an anti-FE material, wherein the third structure is over the second structure; and
a fourth structure comprising metal, wherein the fourth structure is adjacent to the third structure; and
a wireless interface to allow the processor to communicate with another device.

19. The system of claim 18, wherein:
the FE material or the anti-FE material of the third structure comprises strained FE material or strained anti-FE material;
the metal of the fourth structure comprises one or more of: Ti, N, Si, Ta, Cu, Al, Au, W, Co, Pt, or Ru;
the semiconductor material includes one or more of: Si, Ge, Ga, or As;
the ferroelectric material of the third structure includes one or more of: Pb, Ti, Zr, Ba, N Si, La, Al, Y, Hf, H, P, Nb, Li, or Ta; and
the anti-ferroelectric material of the third structure includes one or more of: Si, La, N, Al, Zr, or Hf.

20. The system of claim 18, wherein:
the third structure has a thickness in a range of 10 Angstroms to 19 Angstroms;
the second structure has a thickness between 5 Angstroms and 50 Angstroms; and. the first structure has a thickness in a range of 4 nm to 20 nm.
